(19) United States
(12) Patent Application Publication
(10) Pub. No.: US 2009/0263230 A1
(43) Pub. Date: Oct. 22, 2009

(54) CLUSTER APPARATUS FOR PROCESSING SUBSTRATE AND METHOD FOR PROCESSING SUBSTRATE USING CLUSTER APPARATUS

(76) Inventor: Young Joo HWANG, Seoul (KR)

Correspondence Address: KED & ASSOCIATES, LLP, P.O. Box 221200, Chantilly, VA, 20153-1200, US

(21) Appl. No.: 12/257,628

(22) Filed: Oct. 24, 2008

(30) Foreign Application Priority Data
Apr. 18, 2008 (KR) 10-2008-0035932

(51) Int. Cl. H01L 21/677

(52) U.S. Cl. 414/806; 414/222.09

(57) ABSTRACT

A cluster apparatus for processing a substrate includes a load-lock chamber to receive a substrate, a transfer chamber adjacent to the load-lock chamber, one or more processing chambers each having a side facing the transfer chamber, and a robot in the transfer chamber to unload the substrate from or load the substrate into at least one of the one or more processing chambers or the load-lock chamber. A rotating stage is included in the load-lock chamber to support and rotate the substrate to a desired orientation.

### BACKGROUND

1. Field

One or more embodiments described herein relate to processing substrates.

2. Background

Increases in demand for display devices have led to rapid technological advances. Liquid crystal, plasma, and other flat-panel displays have become popular because they are thin, lightweight, and consume low amounts of power compared to cathode ray tube (CRT) displays. However, because of their complex internal structures, processes used to manufacture flat-panel displays are expensive and more difficult to implement than those used for CRT devices.

### BRIEF DESCRIPTION OF THE DRAWINGS

FIG. 1 is a diagram showing one type of cluster apparatus.

FIG. 2 is a diagram showing one embodiment of another type of cluster apparatus.

FIG. 3 is a diagram showing a rotating stage in the apparatus of FIG. 2.

FIG. 4 is a flowchart showing steps included in one embodiment of a method for processing substrates.

### DETAILED DESCRIPTION

Many liquid crystal displays (LCDs) use thin-film transistor (TFTs) switches for pixel control. Each TFT switch includes a gate electrode, data electrode, pixel electrode, and color filter as well as other components be inserted in a thin-film configuration between a pair of transparent substrates. To form the switch, a deposition process can be used to deposit conductive, semiconductor, and/or dielectric layers, and a photo-lithography process may be used to form each thin film in a desired pattern. A cleaning process may then be implemented to remove unneeded portions and foreign substances.

Each process must be performed under pressure or temperature conditions different from atmospheric conditions and in a clean environment with a minimal amount of suspended foreign substances. In order to meet these requirements, the processes used to manufacture TFT-LCDs are performed in separate chambers.

As with semiconductors, processing integration is required in the field of display device fabrication, taking into consideration technical and economic factors. Accordingly, each process has typically been performed in spatially proximate locations, so that the time taken to convey a substrate between process chambers is minimized. This is done to increase yield and facilitate maintenance and control of equipment for performing the processes. To achieve these objectives, a cluster apparatus may be used.

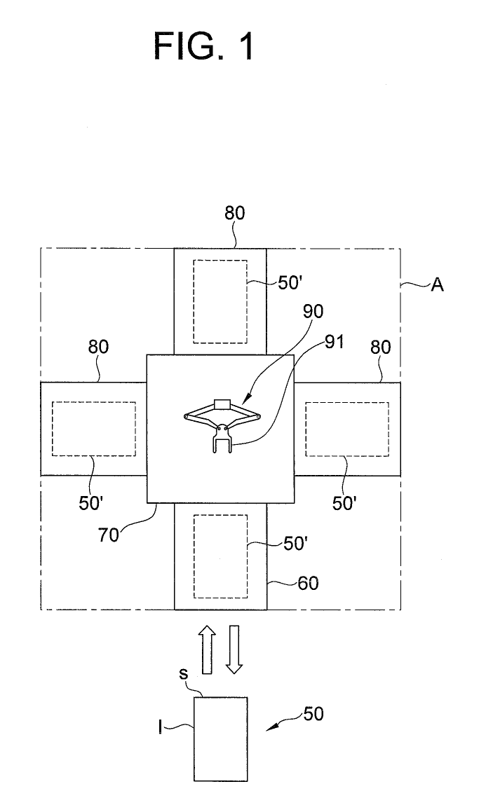

FIG. 1 shows one type of cluster apparatus that includes a load-lock chamber 60, a transfer chamber 70, and a processing chamber 80. The load-lock chamber 60 is used as a temporary storage space for receiving an unprocessed substrate 50 or 50′ from an external location, or for transferring a processed substrate 50 or 50′ to an external location. The reason the load-lock chamber is used as a storage space for the substrates is to prevent bottlenecking as a result of time differences among the different processes. The load-lock chamber functions as a buffer connecting the outside (which is maintained in atmospheric conditions) to each process chamber 80 and transfer chamber 70 (which are not maintained in atmospheric conditions). Depending on the fabrication technique, a plurality of load-lock chambers may be used.

The transfer chamber 70 is located adjacent the load-lock chamber and is used for receiving substrates from the load-lock chamber, and also for transferring substrates to processing chambers 80. To implement this transfer, a robot 90 is installed in the transfer chamber. The robot is typically designed with a fork arm 91 to lift substrates from below and convey them. Also, a lift pin that rises and descends to lift the substrates is provided in chamber 60, to support or release the substrates from the robot.

The processing chambers 80 are installed adjacent transfer chamber 70. An apparatus is installed in each chamber 80 to help facilitate the processes to be performed therein. The processing chambers may include one or more of a heating chamber, a cooling chamber, a deposition chamber, an etching chamber, a cleaning chamber, etc. The number of processing chambers and the apparatuses installed in them may vary according to the processes to be performed.

The substrates 50 and 50′ used for display devices may have a rectangular shape and may be loaded into load-lock chamber 60 short side (S) first. Also, when loading substrates from transfer chamber 70 to each processing chamber 80, the substrates are loaded short side first. Accordingly, installation area (A) of the cluster apparatus (depicted by the dash-dotted line in FIG. 1) is designed to be proportional to the length of the long sides (L) of the substrates.

A cluster apparatus arranged in the manner shown in FIG. 1 is not optimal. Especially when used to fabricate flat-panel displays, installation area (A) tends to be large and only increases in size as the structures of the displays become more and more complex. This is especially so in light of the current trend for very large display devices. Using a large installation area also leads to an increase in manufacturing costs and makes cluster device maintenance and control problematic.

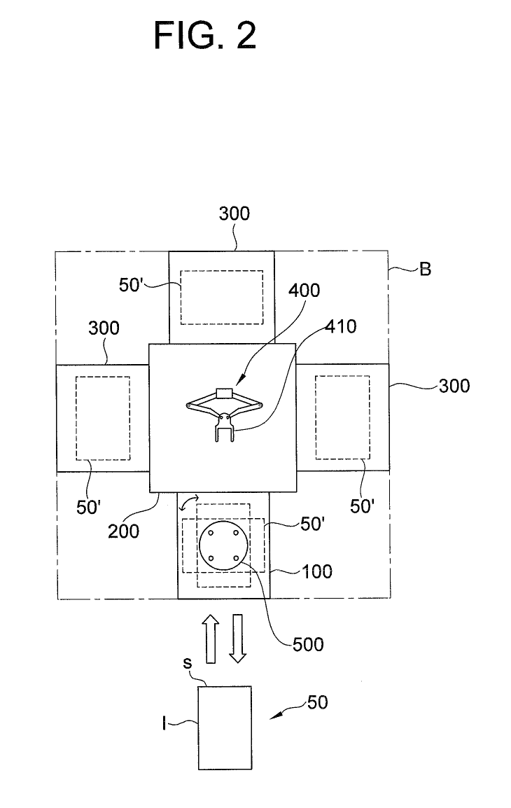

FIG. 2 shows one embodiment of another type of cluster apparatus which, for example, may be used to fabricate flat-panel displays or other electronic devices. As will be described in greater detail below, this apparatus has a reduced installation area and therefore minimizes costs compared with the apparatus of FIG. 1.

As shown, the cluster apparatus may include a load-lock chamber 100, a transfer chamber 200, and one or more processing chambers 300 for processing substrates 50 and 50′. The substrates may be, for example, glass plates to be used in manufacturing LCDs. The substrates may be rectangular in shape having a long side (L) and a short side (S).

The load-lock chamber 100 functions as an entrance of the cluster apparatus for receiving substrates 50 and 50′ from an external source. The substrates are then loaded into one of the processing chambers 300 through transfer chamber 200. The load-lock chamber also functions to unload processed or completely processed substrates from the transfer chamber to an outside location or source. Also, under certain circumstances, the load-lock chamber may temporarily store substrates on standby until various processes are ready to be performed.

According to one embodiment, the transfer chamber and one of more of the processing chambers are maintained at pressure and temperature conditions different from the outside atmosphere. In contrast, the load-lock chamber 100 may be exposed directly to outside conditions and therefore may function as a buffer for retaining pressure and temperature conditions therebetween. While only one load-lock chamber is shown in FIG. 2, those skilled in the art can appreciate that the cluster apparatus may be equipped with a plurality of load-lock chambers in order to meet fabrication requirements.

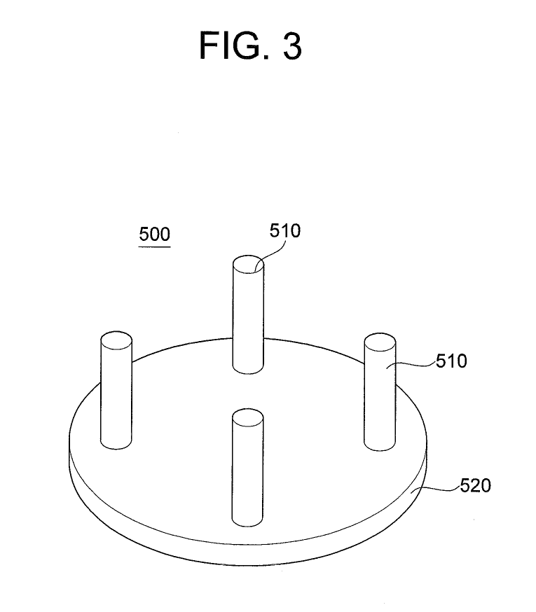

In addition to the aforementioned features, a rotating stage 500 may be included in the load-lock chamber in order to hold substrates 50 and 50′. As shown in FIG. 3, the rotating stage may be configured to include one or a plurality of supporting pins 510 and a rotating block 520. The plurality of supporting pins may be used to support each of the substrates 50 and 50′ from below and may be installed to elevate with respect to the rotating block. And, the rotating block may be installed to rotate with respect to the load-lock chamber. Linear driving members such as hydraulic/pneumatic cylinders, ball-screw assemblies, etc., and rotation driving members such as rotating motors, may be used to elevate the supporting pins and rotate the rotating block, respectively.

The transfer chamber 200 is located adjacent to one side of the load-lock chamber and has a transfer robot 400 installed to unload substrates 50 and 50′ from the load-lock chamber and selectively load the substrates to the process chambers. The transfer robot may be provided with a contractible arm 410 which engages the substrates to support them from below.

A structure that corresponds to support pins 510 on the rotating stage in the load-lock chamber may be provided in each respective processing chamber 300. That is, structures such as pins may also be installed in each processing chamber in order to elevate the substrates, so that arm 410 of the transfer robot can engage the substrates from below. Accordingly, a space may be provided as clearance in order to allow arm 410 to enter. If desired, the transfer robot may be provided with a plurality of arms to enable the substrates to be securely supported. For illustrative purposes, transfer robot 400 in shown in FIG. 2 as having a pair of arms 410. However, in other embodiments, the transfer robot may have three or more arms.

Each of the processing chambers may be provided with a side facing and adjacent to the transfer chamber. Each processing chamber may also have a planar section with a rectangular shape that may correspond to the rectangular shape of the substrates. According to one embodiment, a longer side of each rectangular processing chamber may be located adjacent the transfer chamber.

The processing chambers perform various processes required for processing the substrates 50 and 50′. These processes may include, for example, deposition, photolithography, cleaning, and/or other processes depending on the product to be fabricated. Equipment for performing the processes is installed in the respective processing chambers. Also, if desired, a heating chamber for heating the substrates and a cooling chamber for cooling the substrates may be included among the processing chambers. For illustrative purposes, FIG. 2 depicts three processing chambers, but fewer or more chambers may be included depending, for example, on the number of processes required for fabrication.

In operation, a substrate 50 or 50′ is loaded from an external source or location into load-lock chamber 100. Because the substrate is rectangular in this particular example, it may be loaded into the load-lock chamber short side (S) first. During loading, the substrate is supported by rotating stage 500. This stage rotates and directs the longer side (L) of the substrate toward transfer chamber 200. More specifically, the substrate is loaded from the bottom (in FIG. 2) into the load-lock chamber, and if the transfer chamber is located above the load-lock chamber 100 the rotating stage will rotate the substrate as needed, e.g., by 90°.

Then, transfer robot 400 engages the substrate at a longer side (L) and supports the substrate from below. The robot then unloads the substrate from the load-lock chamber, after which the substrate is rotated, if necessary, and selectively loaded into one of the processing chamber. In so doing, the transfer robot may rotate the substrate to enter one of the processing chambers longer side (L) first.

When processing of the substrate is completed in that chamber, the robot approaches the processing chamber and unloads the substrate. The robot may then load the substrate into another processing chamber or back into the load-lock chamber according to the particular requirements of the fabrication process. If loaded back into the load-lock chamber, the load-lock chamber supports the loaded substrate with the rotating stage and the rotating stage may rotate once more to unloaded the substrate to an external location or source.

Finally, in the embodiment of FIG. 2, the rotating stage may rotate the substrate (e.g., by 90°) so that, for example, the shorter side (S) of the substrate faces transfer chamber 200. The substrate, therefore, may assume its initial position when it entered the load-lock chamber, e.g., with short side (S) unloaded first to the external source or location.

By comparison, the load-lock chamber may have a wider floor area than the load-lock chamber 60 shown in FIG. 1. However, when the substrate is rotated about its geometric center, there is no increase in floor area and the floor area for transfer chamber can therefore be substantially reduced. This is because the longer side of the substrate determines the rotational radius in transfer chamber 70 shown in FIG. 1, while in the cluster apparatus of FIG. 2 the shorter side of the substrate determines the rotational radius. The longer side and shorter side of the substrate may be understood to refer to the distances to the farthest edges of the substrates from a position of the arm 410 of the transfer robot 400 when the arm supports the substrates.

In addition, the processing chambers 80 in FIG. 1 all have the short side of the substrate facing and adjacent to transfer chamber 70. However, in the cluster apparatus of FIG. 2, the processing chambers may have the longer sides of the substrates facing and adjacent to transfer chamber 200. Because corresponding sides of the processing chambers correspond to sides of the substrates, the overall installation area of the cluster apparatus of FIG. 2 may advantageously be substantially reduced. As a result, the installation area (B) depicted by the dash-dotted line in FIG. 2 can be much smaller than the installation area (A) depicted by the dash-dotted line in FIG. 1.

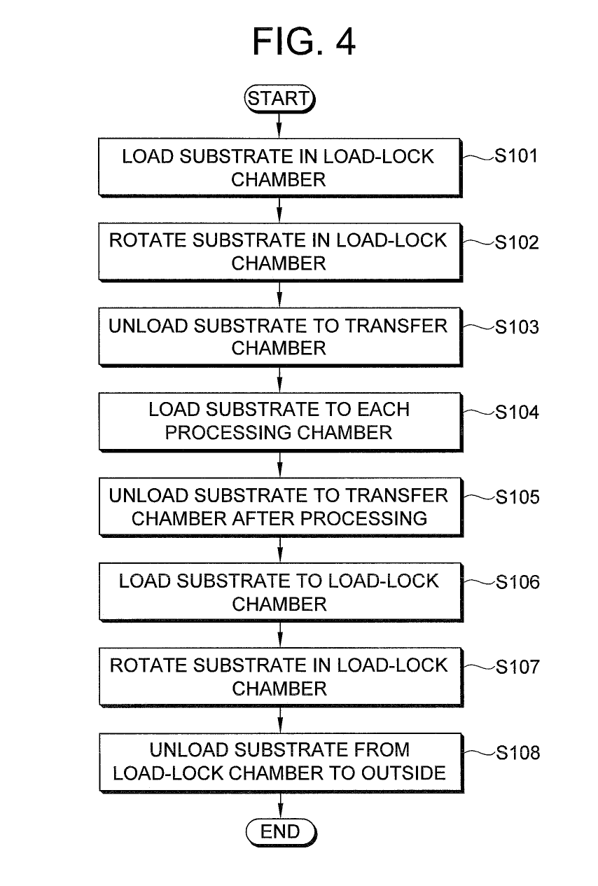

FIG. 4 shows steps included in one embodiment of a method for processing substrates, which method may be performed, for example, using the cluster apparatus shown in FIG. 2.

The cluster apparatus is configured with the load-lock chamber at a location that will allow it to receive one or more substrates from an external source or location, and that will allow it to return the processed substrates to the same or a different external source or location. The transfer chamber is provided adjacent to the load-lock chamber, and one or more processing chambers are provided having respective sides facing and adjacent to the transfer chamber. Each processing chamber performs a predetermined process on a substrate received from the transfer chamber. With this configuration in mind, the following operations may be performed.

First, a substrate is loaded into the load-lock chamber in a substrate loading operation S101. The substrate may, for example, be a rectangular board and may be loaded short side first into the load-lock chamber.

When the substrate is loaded into the load-lock chamber, the substrate is rotated in a substrate rotating operation S102 so that a longer side of the substrate faces the transfer chamber. The angle of rotation may vary based on a direction in which the load-lock chamber is oriented to receive the substrate and the position of the transfer chamber relative to the load-lock chamber. For example, as shown in FIG. 2, when the loading direction of the substrate in the load-lock chamber and the position of the transfer chamber with respect to the load-lock chamber are in a straight line, the substrate is rotated 90° within the load-lock chamber. Then, the longer side of the substrate faces the transfer chamber.

Next, the rotated substrate is unloaded from the load-lock chamber to the transfer chamber in a first substrate loading operation S103. The unloading process may be performed by an automated device such as the robot provided in the transfer chamber. In the first substrate loading operation S103, the substrate is rotated so that its longer side faces the transfer chamber, and thus the substrate is unloaded to the transfer chamber with one of its longer sides first.

The unloaded substrate is loaded from the transfer chamber to a processing chamber in a process loading operation S104. When a plurality of processing chambers is provided, the substrate is loaded into a selected one of the processing chambers. The selection may be based on the particular process that is required to be performed on the substrate requires performed.

By implementing the aforementioned process, the cluster apparatus can perform the same processes as those in FIG. 1 but in a substantially smaller installation area. After the substrate has been passed through the processing chambers, the substrate may be unloaded from the cluster apparatus as described below. That is, a substrate that has undergone processing in the respective processing chambers may be unloaded again to the transfer chamber in a process completion operation S105.

In a second substrate loading operation S106, the unloaded substrate is reloaded from the transfer chamber to the load-lock chamber. During this operation, a longer side of the substrate may be unloaded first to the load-lock chamber. When required, the process completion operation S105 and the process loading operation S104 may be repetitively performed numerous times prior to the second substrate loading operation S106, according to the processes required to be performed for substrate processing.

When the second substrate loading operation S106 is completed, the substrate is re-rotated in the load-lock chamber in a second substrate rotating operation S107, so that a shorter side of the substrate faces an external location or source. As previously described, when the configuration of the cluster apparatus is viewed in FIG. 2, loading the substrate with a longer side first into the load-lock chamber and then rotating the substrate by 90° within the load-lock chamber (S107) causes a shorter side of the substrate to face the external location or source.

Thereafter, the substrate is unloaded from the load-lock chamber to the external location or source in a substrate unloading operation S108. Then, the substrate may assume its original position when it was loaded into the load-lock chamber; that is, a short side of the substrate is unloaded first from the load-lock chamber.

The cluster apparatus described relative to FIGS. 2 to 4 may have an installation area proportional to the length of the shorter side of the substrate, which represents a substantial reduction in the installation area compared to a case where the installation area is proportional to the length of the longer side.

Also, the cluster apparatus has a rotating stage in a load-lock chamber and adjusting the arrangement of the processing chambers, etc., to enable with minimal modifications a reduction of the installation areas of cluster apparatuses that have already been installed.

A method for processing a substrate with a cluster apparatus according to the present invention can also load or unload a substrate with the longer side first through a 90-degree rotation (even when the substrate is loaded with the shorter side first), so that the longer sides of the processing chambers are oriented facing and adjacent to the transfer chamber, thereby enabling the overall installation area occupied by the cluster apparatus to be minimized.

In the foregoing embodiments, the substrates and processing chambers have been described as having rectangular shapes. However, in other embodiments the substrates may have different shapes (e.g., circular, triangular, etc.) and the processing chambers may have a shape capable of allowing the substrates to be loaded or unloaded, although the shapes of the chamber may not be the same as the shapes of the substrates.

In summary, the cluster apparatus in accordance with one or more of the aforementioned embodiments has a substantially reduced installation area compared with other cluster apparatuses. The cluster apparatus is also capable of being adapted to existing installation spaces that use existing equipment through minimal modifications. In addition, a method for processing substrates is provided that may use a cluster apparatus as previously described which is capable of processing substrates within a minimal area.

According to one embodiment, a cluster apparatus for processing a substrate includes: a load-lock chamber for receiving a substrate from an outside and temporarily storing the substrate; a transfer chamber adjacent to the load-lock chamber; a plurality of processing chambers, each having one side adjacent to the transfer chamber; a transfer robot installed in the transfer chamber to unload the substrate from one of the plurality of processing chambers and the load-lock chamber or storing the substrate; and a rotating stage installed in the load-lock chamber to rotatably support the substrate. Each processing chamber may have a horizontal area of a rectangular shape, and one longer side of the rectangular horizontal area of each processing chamber may be adjacent to the transfer chamber. Also, the transfer robot may include at least one pair of arms for supporting the substrate. In addition, the rotating stage may include a plurality of supporting pins that are driven to elevate while supporting the substrate, and a rotating block supporting the plurality of supporting pins and driven to rotate.

The substrate may be a rectangular board, a shorter side of the substrate may be first loaded when the substrate is loaded from the outside into the load-lock chamber; the rotating stage may rotate the substrate on the same horizontal plane to direct a longer side of the substrate toward the transfer chamber; a longer side of the substrate may first be loaded when the substrate is loaded from the transfer chamber to the load-lock chamber; and the rotating stage may rotate the substrate on the same horizontal plane to direct a shorter side of the substrate toward the outside.

According to another embodiment, a method for processing a substrate with a cluster apparatus includes: performing a substrate supplying operation for supplying a substrate from an outside to a load-lock chamber; performing a first substrate rotation operation for rotating the substrate in the load-lock chamber; performing a first substrate loading operation for loading the rotated substrate to a transfer chamber adjacent to the load-lock chamber; and performing a process initializing operation for selectively supplying the loaded substrate to a plurality of processing chambers adjacent to the transfer chamber.

The method may further include performing a process completion operation for loading the substrate that has completed processing in the processing chambers to the transfer chamber; performing a second substrate loading operation for supplying the loaded substrate to the load-lock chamber; performing a second substrate rotation operation for rotating the substrate in the load-lock chamber; and performing a substrate unloading operation for unloading the substrate from the load-lock chamber to the outside.

The substrate may be a rectangular board, the substrate supplying operation may include supplying a shorter side of the substrate first to the load-lock chamber; the first substrate rotation operation may include rotating the substrate on the same horizontal plane to direct a longer side of the substrate toward the transfer chamber; the second substrate loading operation may include supplying a longer side of the substrate first to the load-lock chamber; the second substrate rotation operation may include rotating the substrate on the same horizontal plane to direct a shorter side of the substrate toward the outside; and the substrate unloading operation may include unloading a shorter side of the substrate first from the load-lock chamber.

Any reference in this specification to “one embodiment,” “an embodiment,” “example embodiment,” etc., means that a particular feature, structure or characteristic described in connection with the embodiment is included in at least one embodiment of the present invention. The appearances of such phrases in various places in the specification are not necessarily all referring to the same embodiment. Further, when a particular feature, structure or characteristic is described in connection with any embodiment, it is submitted that it is within the purview of one skilled in the art to affect such feature, structure or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, numerous variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A cluster apparatus for processing a substrate, comprising:
a load-lock chamber to receive a substrate;
a transfer chamber adjacent to the load-lock chamber;
one or more processing chambers, each having a side facing the transfer chamber;
a robot in the transfer chamber to unload the substrate from or load the substrate into at least one of the one or more processing chambers or the load-lock chamber; and
a rotating stage in the load-lock chamber to support and rotate the substrate to a desired orientation.

2. The cluster apparatus of claim 1, wherein each of the one or more processing chambers has a horizontal area in a rectangular shape, and one longer side of the rectangular horizontal area is adjacent to the transfer chamber.

3. The cluster apparatus of claim 1, wherein the robot has at least one pair of arms for supporting the substrate.

4. The cluster apparatus of claim 1, wherein the rotating stage comprises:
one or more support pins to support and elevate the substrate; and
a rotating block supporting the one or more support pins.

5. The cluster apparatus of claim 1, wherein:
the substrate has a rectangular shape with a shorter side loaded first into the load-lock chamber from an external location, and
the rotating stage rotates the substrate to direct a longer side of the substrate towards the transfer chamber, the longer side of the substrate loaded first into the transfer chamber, the rotating stage further rotating the substrate to direct the shorter side of the substrate towards the load-lock chamber after processing is performed in at least one of the one or more processing chambers.

6. The cluster apparatus of claim 1, wherein the side of each processing chamber facing the transfer chamber has a width that corresponds to a side of the substrate facing the processing chamber when unloaded from the transfer chamber.

7. The cluster apparatus of claim 1, wherein the processing chambers have a same orientation within an installation area relative to the transfer chamber when the transfer chamber faces each of the processing chambers.

8. The cluster apparatus of claim 7, wherein the load-lock chamber has an orientation relative to the transfer chamber different from the processing chambers.

9. The cluster apparatus of claim 1, wherein the rotating stage rotates the substrate by a same predetermined angle when loading the substrate from the transfer chamber into the processing chambers.

10. A method for processing a substrate, comprising:
loading a substrate into a load-lock chamber;
rotating the substrate in the load-lock chamber;
loading the rotated substrate into a transfer chamber adjacent to the load-lock chamber; and
selectively loading substrate from the transfer chamber into a processing chamber adjacent to the transfer chamber.

11. The method of claim 10, further comprising:
after the substrate has been processed, loading the substrate into the transfer chamber;
transferring the substrate into the load-lock chamber;
rotating the substrate in the load-lock chamber; and
unloading the substrate from the load-lock chamber to an external location.

12. The method of claim 10, wherein:
the substrate has a rectangular shape and a shorter side of the substrate is loaded first into the load-lock chamber;
the substrate is rotated to direct a longer side of the substrate toward the transfer chamber, the longer side of the substrate loaded first into the transfer chamber; and
the substrate is rotated to direct a shorter side of the substrate toward an external location when the substrate is transferred from the load-lock chamber after processing.

13. The method of claim 10, wherein a long side of the processing chamber faces a long side of the substrate when the substrate is rotated within the transfer chamber for loading into the processing chamber.

14. The method of claim 13, wherein a short side of the processing chamber is substantially perpendicular to the long side of the substrate when the substrate is rotated within the transfer chamber for loading into the processing chamber.

15. The method of claim 10, wherein the processing chamber and the substrate have similar shapes.

16. The method of claim 10, wherein a plurality of processing chambers are located adjacent to the transfer chamber, the processing chambers having a same orientation relative to the transfer chamber.

17. The method of claim 16, wherein the load-lock chamber has an orientation different from the processing chambers relative to the transfer chamber.

18. The method of claim 16, wherein the substrate is rotated by substantially a same angle when loaded from the transfer chamber into each of the processing chambers.

19. The method of claim 10, wherein the substrate is rotated by a rotating stage in the load-lock chamber, said stage including one or more support pins for supporting the substrate in an elevated position.

20. The method of claim 10, wherein the substrate has a first orientation when loaded into the lock-lock chamber and the substrate has a second orientation different from the first orientation when loaded into the processing chamber.
